(19) United States
(12) Patent Application Publication
(10) Pub. No.: US 2010/0040848 A1
(43) Pub. Date: Feb. 18, 2010

(54) NANO MATERIAL CLUSTER STRUCTURE

(75) Inventor: Youngtack Shim, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: SEOUL NATIONAL UNIVERSITY RESEARCH & DEVELOPMENT BUSINESS FOUNDATION (SNU R&DB FOUNDATION), Seoul (KR)

(21) Appl. No.: 12/192,029

(22) Filed: Aug. 14, 2008

(51) Int. Cl. B32B 3/22; G03F 7/20; B82B 1/00

(52) U.S. Cl. 428/209; 430/312; 977/742; 977/762

(57) ABSTRACT

There is provided a novel nano material cluster structure. The nano material cluster structure comprises a conductor block and a plurality of first nano material strands protruding from a surface of the conductor block. The first nano material strands extend from the conductor block in a coplanar relationship. A novel method of preparing a nano material cluster structure is also provided. The method comprises providing a layered structure having multiple layers on a substrate. The multiple layers comprise a layer having nano material strands therein. The method also comprises patterning the layered structure to define one or more recesses. The nano material strands are partially exposed through said one or more recesses. The method further comprises filling the one or more recesses with a conductive material to enclose the partially exposed nano material strands.

### TECHNICAL FIELD

The present disclosure relates generally to nano material cluster structures and techniques for preparing the same.

### BACKGROUND

One of the principal themes in the field of nanotechnology is the development of nano materials on an atomic or molecular scale, that is, smaller than a micron. New or preeminent properties of the nano materials are attributed to their nanoscale size. Compared to macroscale materials, the materials reduced to nanoscale display very different properties, which enable them to be adapted for various applications. For example, an opaque substance of macroscale may become a transparent substance of nanoscale, a stable substance of macroscale may turn into a combustible substance of nanoscale, a solid substance of macroscale may be converted into a liquid substance of nanoscale at room temperature, or an insulator of macroscale may become a conductor of nanoscale. Due to such novel properties associated with nanoscale, the nano materials have been widely applied in various fields.

However, despite their superior mechanical, chemical or electrical properties, there have been certain limitations in using the nano materials due to the difficulty in aligning or handling such small materials in making a useful structure. In order to fully utilize and apply the preeminent properties of the nano materials in various fields, it is necessary to conceive various reliable nano material cluster structures and suitable mechanisms for positioning the same in a desired arrangement.

### SUMMARY

The present disclosure provides a novel nano material cluster structure. The nano material cluster structure may comprise a conductor block and a plurality of first nano material strands protruding from a surface of the conductor block. The plurality of first nano material strands may extend from the conductor block in a coplanar relationship.

In one embodiment, the nano material cluster structure may further comprise a plurality of second nano material strands protruding from the surface of the conductor block. The plurality of second nano material strands may extend from the conductor block in a coplanar relationship. The plurality of second nano material strands may be also parallel with the first nano material strands. Alternatively, the plurality of second nano material strands may be arranged at a preset angle with respect to the first nano material strands.

In another embodiment, the conductor block may have a shape of hexahedron.

In yet another embodiment, the conductor block may include Ag, Cu or Al.

In yet another embodiment, the first nano material strands may be arranged in parallel with each other.

In yet another embodiment, the second nano material strands may be arranged in parallel with each other.

In yet another embodiment, the first nano material strands may be equally spaced apart from the adjacent one.

In yet another embodiment, the second nano material strands may be equally spaced apart from the adjacent one.

In yet another embodiment, the first and second nano material strands may include carbon nanotubes or carbon nanowires.

In yet another embodiment, the first and second nano material strands may have a same length.

The present disclosure provides another novel nano material cluster structure. The nano material cluster structure may comprise two conductor blocks and a plurality of first nano material strands each having two end portions. The plurality of first nano material strands may extend from one of the two conductor blocks to the other conductor block such that the two end portions of each of the first nano material strands are inserted into the respective conductor blocks.

In one embodiment, the two conductor blocks may be arranged in parallel with each other.

The present disclosure provides yet another novel nano material cluster structure. The nano material cluster structure may comprise a conductor block having two opposing surfaces, a first set of first nano material strands protruding from one of the two opposing surfaces of the conductor block, and a second set of first nano material strands protruding from the other surface. The first set of first nano material strands may be coplanar with said second set of first nano material strands.

The present disclosure provides a novel method of preparing a nano material cluster structure. The method may comprise providing a layered structure having multiple layers on a substrate. The multiple layers may comprise a layer having nano material strands therein. The method may also comprise patterning the layered structure to define one or more recesses. The nano material strands may be partially exposed through said one or more recesses. The method may further comprise filling the one or more recesses with a conductive material to enclose the partially exposed nano material strands.

In one embodiment, the method may further comprise detaching the substrate.

In another embodiment, the nano material strands may be arranged in parallel to each other.

In yet another embodiment, the one or more recesses may be respectively arranged in perpendicular to an extending direction of the nano material strands.

In yet another embodiment, the nano material strands may include carbon nanotubes or carbon nanowires.

In yet another embodiment, at least one of the recesses may be defined so that end portions of the nano material strands are exposed through said recess.

In yet another embodiment, the step of providing the layered structure may comprise depositing a first photoresist layer on the substrate, patterning the first photoresist layer to define multiple grooves, filling the grooves with nano materials to cause the nano material strands to match the respective grooves, and depositing a second photoresist layer to cover the first photoresist layer having the nano material strands therein.

In yet another embodiment, the method may further comprise removing the first and second photoresist layers after filling the conductive material.

In yet another embodiment, a thickness of the nano material strands may be smaller than a depth of the multiple grooves.

In yet another embodiment, the method may further comprise trimming ends of the nano material strands so that they are left open rather than enclosed by the conductive material such that the nano material strands have a substantially equal length.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIGS. 1A and 1B show a schematic diagram of a nano material cluster structure in accordance with one embodiment;

FIGS. 2 to 15 show a series of steps for preparing a nano material cluster structure in accordance with one embodiment;

FIG. 16 shows a schematic diagram of a nano material cluster structure in accordance with another embodiment;

FIGS. 17 to 20 show a series of steps for preparing a nano material cluster structure in accordance with another embodiment;

FIG. 21 shows a schematic diagram of a nano material cluster structure in accordance with yet another embodiment, and FIGS. 22 to 25 show a series of steps for preparing a nano material cluster structure in accordance with yet another embodiment.

### DETAILED DESCRIPTION

In the following detailed description, reference is made to the accompanying drawings, which form a part hereof In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and make part of this disclosure.

### Embodiment 1

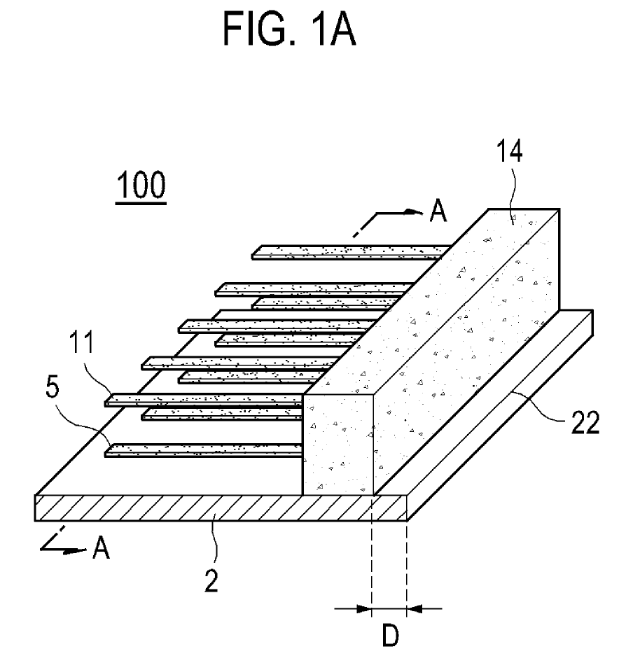

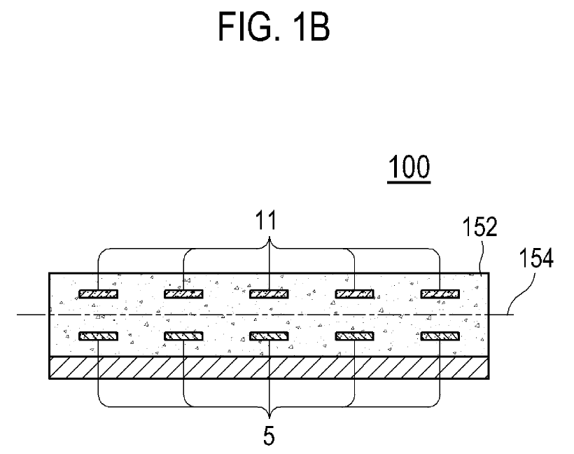

FIGS. 1A and 1B show a schematic diagram of a nano material cluster structure 100 in accordance with one embodiment.

FIG. 1A shows an oblique view of the nano material cluster structure from an upper right side position and FIG. 1B shows a longitudinal cross-sectional side view of the nano material cluster structure along the line A-A′. As shown in FIG. 1A, the nano material cluster structure 100 includes a substrate 2.

The substrate 2 may have the shape of a thin plate including relatively large top and bottom surfaces opposite to each other and two pairs of slim and long lateral surfaces. The substrate 2 may be formed from materials that are appropriately selected in consideration of features required for a specific application field. For example, to allow the resulting structure to be used in a transparent device, transparent glass, indium tin oxide or other transparent or translucent materials may be used to provide the substrate 2.

The nano material cluster structure 100 may also include a conductor block 14 formed on the substrate 2 to longitudinally extend in line with one edge 22 of the substrate 2 and spaced apart by a predetermined width D therefrom. The predetermined D may range from a few % to a substantial portion of a length of the substrate 2 depending on the intended use of the structure 100. The conductor block 14 may have the shape of a rectangular hexahedron including longitudinally extending top and bottom surfaces. The conductor block 14 may also have two longitudinally extending lateral surfaces and two end surfaces arranged between and in perpendicular to the top and bottom surfaces. The bottom surface of the conductor block 14 may be attached to the top surface of the substrate 2. The conductor block 14 may be formed from one or more electrically conductive materials, including, for example, but not limited to, Ag, Cu, Al, etc.

The nano material cluster structure 100 may further include a first set of nano material strands 5 protruding from one lateral surface of the conductor block 14 located distal to the edge 22 of the substrate 2. The first set of nano material strands 5 may be arranged on the surface 142 below and in a parallel relationship with a horizontal center line indicated by reference numeral 144. The first set of nano material strands 5 may be further arranged in a coplanar relationship with each other. Each of the first nano material strands 5 may have the shape of an elongated tube or rod. The first nano material strands 5 may extend in a substantially parallel relationship with each other in the lateral direction perpendicular to the conductor block 14. The length of the laterally extending portion of the first nano material strands 5 may be relatively longer than the width or thickness of the same. In one embodiment, the nano material strands 5 may include, for example, carbon nanotubes, carbon nanowires or other elongated nano materials. Although the illustrated embodiment shows the first nano material strands as being equally spaced apart from an adjacent one, it may be possible to arrange the first nano material strands 5 so that they are unequally or irregularly spaced apart from each other.

The nano material cluster structure 100 may further include a second set of nano material strands 11 protruding from the lateral surface 142 of the conductor block 14. The second set of nano material strands 11 may be arranged on the surface 142 above and in a parallel relationship with the horizontal center line 144. Also, the second set of nano material strands 11 may be arranged in a coplanar relationship with each other and further in parallel with the first nano material strands 5. Each of the second nano material strands 11 may have an elongated shape which may be identical/similar to or different from the shape of the first strands 5.

The second nano material strands 11 may extend in a substantially parallel relationship in the lateral direction perpendicular to the conductor block 14. The length of the laterally extending portion of the second nano material strand 11 may be relatively longer than the width or thickness of the same. In one embodiment, the nano material strands 11 may include, for example, carbon nanotubes or carbon nanowires. Although the illustrated embodiment shows the second nano material strands as being equally spaced apart from an adjacent one, it may be possible to arrange the second nano material strands 11 so that they are unequally or irregularly spaced apart from each other.

As shown in FIG. 1A, all the nano material strands 5, 11 have the same length. However, the present disclosure is not limited to such an arrangement. In one embodiment, the first and second nano material strands may have differing lengths.

Although the illustrated embodiment in FIG. 1A shows the first and second sets of nano material strands 5, 11 protruding from the lateral surface 142 of the conductor block 14, it may be possible that the nano material cluster structure 100 may be arranged to include only the first set of nano material strands 5 protruding from the lateral surface 142 of the conductor block 14. Alternatively, it may be possible for the nano material cluster structure 100 to include three or more sets of nano material strands. Further, although the first and second sets of nano material strands 5, 11 are illustrated to be parallel with each other in FIG. 1A, the present disclosure is not limited to such an arrangement. In one embodiment, it may be possible to arrange the first or second set of nano material strands to be radially extended from the conductor block. Although the illustrated embodiment in FIG. 1A shows only five nano material strands included in each set of nano material strands 5, 11, it should be recognized herein that less or more nano material strands may be included in each set of nano material strands 5, 11.

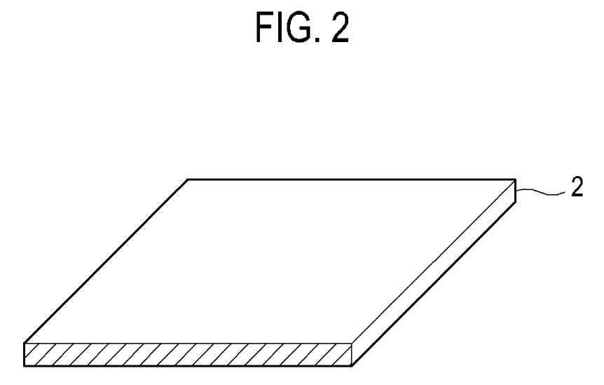

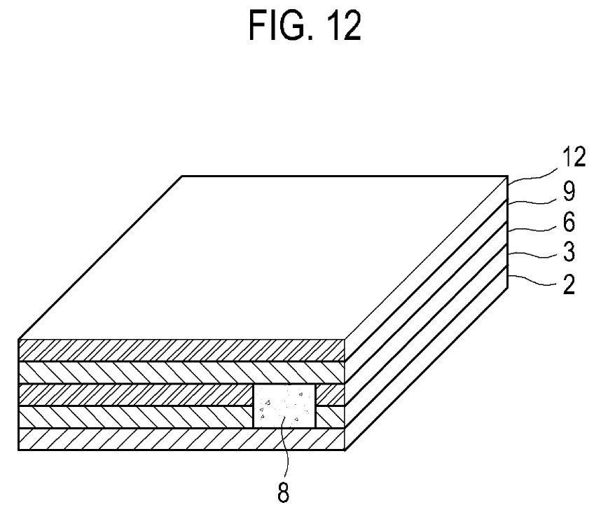

FIGS. 2 to 15 show a series of steps for preparing a nano material cluster structure in accordance with one embodiment.

As shown in FIG. 2, a substrate 2 is provided. As described above, the substrate 2 may be selected according to features required for a specific application field. For example, to allow the resulting structure to be used in an optical device, the substrate 2 may be transparent, translucent or opaque. In another example, the substrate 2 may be electrically conductive, semi-conductive or insulative when the resulting structure is to be used as an electronic device. Similarly, the substrate 2 may be ferromagnetic, paramagnetic, ferromagnetic or the like when the resulting device is to be used in a magnetic device.

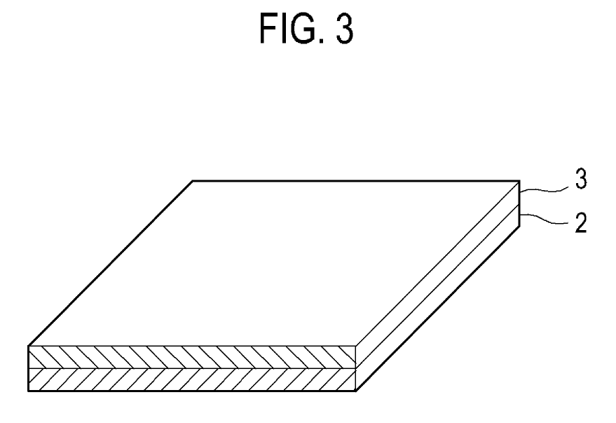

As shown in FIG. 3, a first photoresist layer 3 is deposited on the substrate 2 to a preset thickness. The thickness of the photoresist layer 3 may be appropriately selected by those skilled in the art in consideration of the relationship between etching resistance and resolution. The first photoresist layer 3 may have a high resolution, which is sufficient enough to enable a subsequent nanoscale fine patterning. It should be noted that the first photoresist layer 3 may be comprised of one or more materials selected among various conventional photoresist materials well known to those skilled in the art.

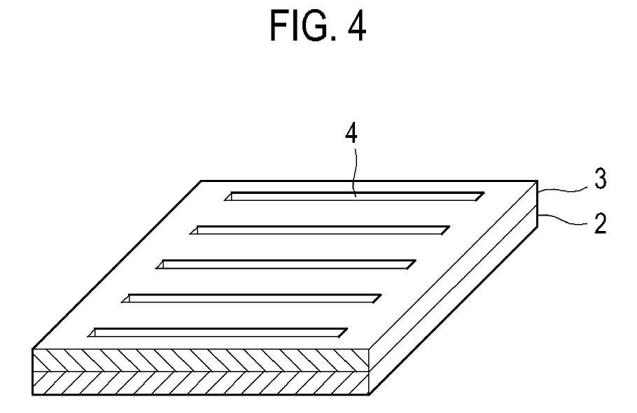

Referring to FIG. 4, the first photoresist layer 3 may be patterned by photolithography or other equivalent processes in order to define one or more grooves 4 thereon. Each groove 4 may be elongated and have a length much longer than a width in the longitudinal direction. As shown in FIG. 4, the grooves 4 are arranged in parallel with each other. Further, the grooves 4 may be substantially equally spaced apart from the adjacent one. However, it should be noted that the present disclosure is not limited to such an arrangement. According to one embodiment, one or more grooves formed in the first photoresist layer 3 may have different lengths or widths, may extend in different directions, may be radially arranged, etc. Further according to one embodiment, the grooves formed in the first photoresist layer 3 may not be equally spaced from the adjacent one.

In one embodiment, the first photoresist layer 3 may be exposed to ultraviolet lights through a mask having a fine groove pattern image. The exposed photoresist layer 3 may then be developed to form the grooves 4 by using a chemical etchant, a plasma gas or other equivalent materials. Alternatively, the photoresist layer 3 may be patterned by any other similar processes such as those using lasers, ion beams and the like.

The depth of the grooves 4 is equal to or smaller than the thickness of the first photoresist layer 3. In one embodiment, it may be required to form the grooves 4 as shallow as possible. In case of using a chemical etching method, a selected etchant, a selected etching time, etc. may control the depth of the grooves 4. In other cases, an intensity of the lasers or ion beams, a period of exposure or other process variables associated therewith may control such a depth.

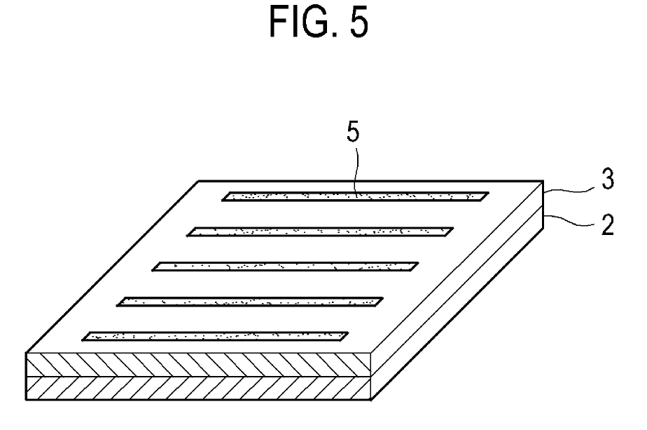

Referring to FIG. 5, the nano material is then deposited into the grooves 4 to define nano material strands 5 matching the respective grooves 4. The nano material strands 5 may include, for example, but are not limited to, carbon nanotubes, carbon nanowires, other elongated nano materials, quantum dots and the like.

In one embodiment, a suspension, an emulsion, a solution or liquid mixture of nano materials (hereinafter, collectively referred to as “the suspension of nano materials”) may be poured on top of the first photoresist layer 3. The suspension of nano materials may migrate into the grooves 4 by gravity, diffusion or other mechanical, electrical or magnetic forces and define the shapes and sizes matching those of the grooves 4.

In one embodiment, a gas jet device may be used to eject a stream of gas to sweep the poured suspension of nano materials across the first photoresist layer 3. In such a case, a larger amount of nano materials may enter the grooves due to the pressure of the ejected gas stream. In one embodiment, after supplying the suspension of nano materials over the grooves to allow at least some of the nano materials to enter the grooves, a gas jet device may be applied on the suspension of nano materials to cause the nano-materials, which are disposed outside the groove, to further move into the grooves and be trapped therein. Alternatively, centrifugal force may be used to allow a larger amount of nano materials to enter the grooves 4. When diffusing the nano materials into the grooves on the substrate using the centrifugal force, the substrate may be placed in a substantially circular fluid channel, which is filled with a fluid medium containing the nano materials. The fluid medium may be caused to be rotated within the fluid channel, wherein the nano materials may then be diffused into the grooves on the substrate. In other alternatives, external electric or magnetic fields may be generated and attract the nano materials into the grooves 4 when such materials respond to said fields.

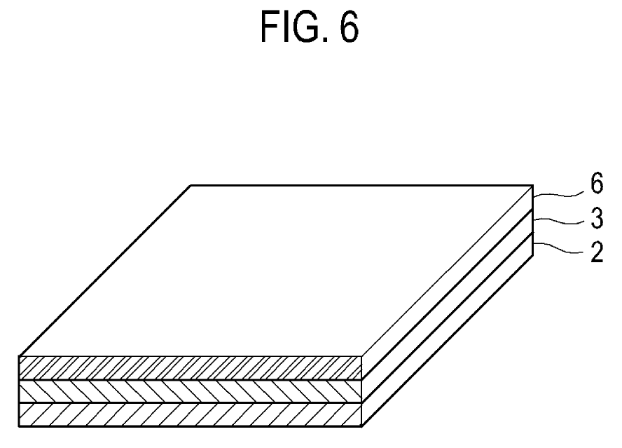

As shown in FIG. 6, a second photoresist layer 6 is deposited onto the first photoresist layer 3 so as to entirely cover the grooves 4 having the nano material strands 5 disposed therein. It should be noted that the second photoresist layers 6 may comprise materials that are identical to those of the first photoresist layer 3. Alternatively, the second photoresist layer 6 may comprise materials that are different from those of the first photoresist layer 3 as long as it can be removed together with the first photoresist layer in one patterning stage (or in multiple consecutive stages) as explained below. The process of depositing the second photoresist layer 6 is similar to the process of depositing the first photoresist layer 3. As such, a detailed explanation regarding said process is omitted herein.

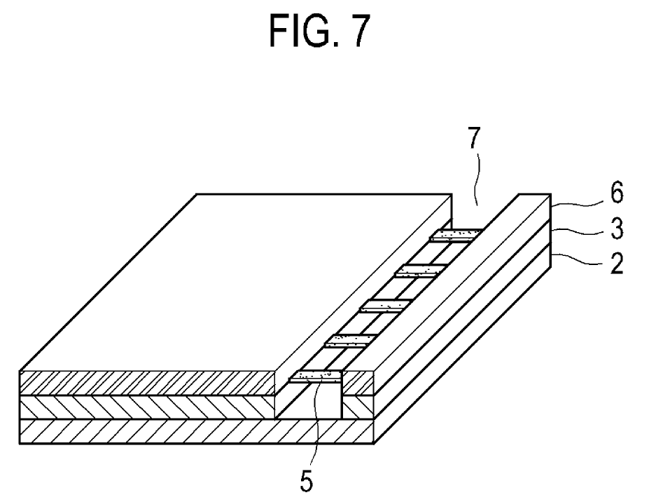

Thereafter, the first and second photoresist layers 3, 6 are patterned by photolithography or other equivalent processes to define a recess 7 passing through the first and second photoresist layers 3, 6, as shown in FIG. 7. The recess 7 is formed longitudinally and in proximate to one edge 22 of the substrate 2 so as to have a width corresponding to a resultant conductor block 14, as explained below. Photolithography or other equivalent processes are performed enough to remove a desired portion of the first photoresist layer 3 disposed under the second photoresist layer 6 to a desired depth. The first and second photoresist layers 3, 6 are patterned away to expose the substrate 2 through the recess 7. Alternatively, in one embodiment, the first and second photoresist layers 3, 6 may be patterned away to leave a part of the first photoresist layer within the recess 7.

As shown in FIG. 7, the first and second layers 3, 6 are removed away to expose end portions of the nano material strands 5 through the recess 7. Alternatively, in another embodiment, another area of the first and second layers 3, 6 may be removed away to expose portions of the nano material strands 5 other than the end portions through the recess 7. In either case, it should be noted that all the nano material strands 5 extending in the grooves 4 of the first photoresist layer 3 should be exposed in part through the recess 7.

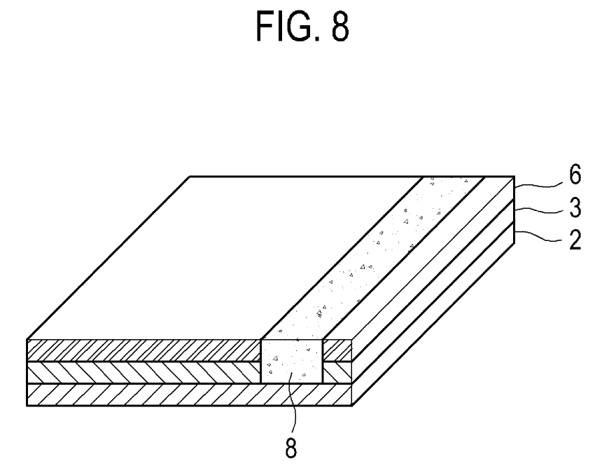

Thereafter, a conductive material is filled in the recess 7 to physically and electrically contact and enclose the exposed end portions of the nano material strands 5 so as to provide a conductor block 8, as shown in FIG. 8. As a result, the nano material strands 5 are guaranteed to make electrical contact with the conductor block 8. In one embodiment, the conductive material may include, for example, but is not limited to, Ag, Cu, Al, etc.

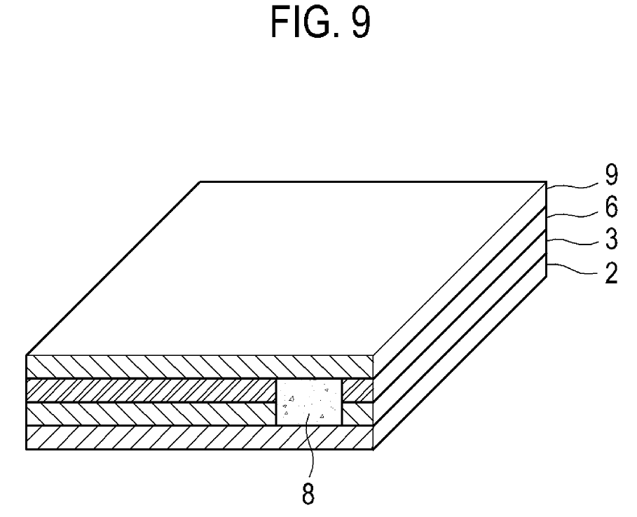

Thereafter, the above series of steps, i.e., depositing and patterning a photoresist layer to make grooves, filling the grooves with nano materials, depositing and patterning another photoresist layer to make a recess, and filling the recess with conductive material may be repeated again, as explained below with reference to FIGS. 9 to 14. Such a repetition may be performed once or more depending on a specific application.

Referring now to FIG. 9, a third photoresist layer 9 is deposited on top of the conductor block 8 and the remaining second photoresist layer 6. The materials selected for the third photoresist layer 3 and the detailed deposition process may be similar to those of the first photoresist layer 3 shown in FIG. 3. Alternatively, in one embodiment, materials different from the first photoresist layer 3 may be selected for the third photoresist layer 9 and a different process may be employed to deposit the third photoresist layer 9.

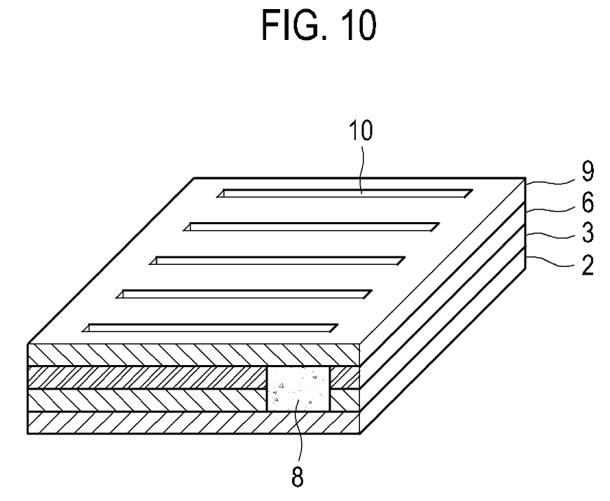

As shown in FIG. 10, the third photoresist layer 9 is patterned by photolithography or other equivalent processes to define one or more grooves 10 thereon. The grooves 10 are respectively arranged to identically correspond to each of the grooves 4 on the first photoresist layer 3 by one-to-one relationship. Alternatively, in one embodiment, the grooves 10 may be arranged differently from the arrangement of the grooves 4 on the first photoresist layer 3 unless this prevents the implementation of the idea of the present disclosure. The detailed patterning process for the third photoresist layer may be similar to the process of patterning the first photoresist layer 3. Thus, detailed explanations regarding the patterning process are omitted herein.

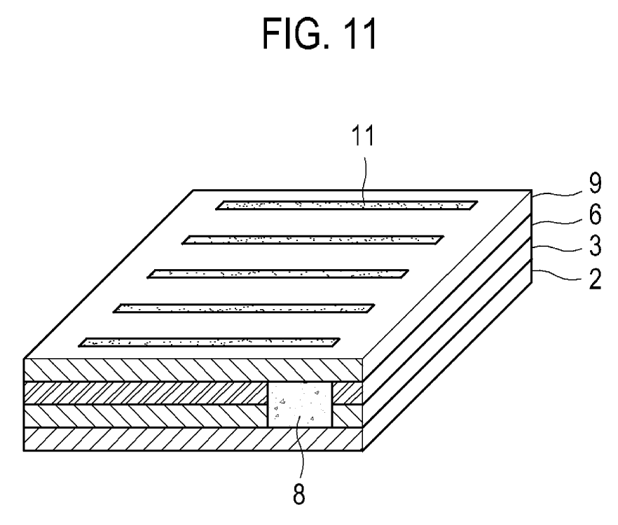

As shown in FIG. 11, the nano materials are then deposited into the grooves 10 to define second nano material strands 11 respectively matching the grooves 10. It should be noted that the selected nano materials for the strands 11 may or may not be the same as the nano materials for the strands 5. The detailed process of forming the nano material strands 11 may be similar to that of the nano material strands 5. Thus, detailed explanations regarding such a process are omitted herein.

Thereafter, a fourth photoresist layer 12 is deposited onto the third photoresist layer 9 so as to entirely cover the grooves 10 having the nano material strands 11 disposed therein. The fourth photoresist layer 12 may comprise materials identical to those of the third photoresist layer 9. Alternatively, the fourth photoresist layer 12 may comprise materials different from those of the third photoresist layer 9 as long as it can be removed together with the third photoresist layer 9 in one patterning stage as explained below. The process of depositing the fourth photoresist layer 12 is similar to the process of depositing the third photoresist layer 3.

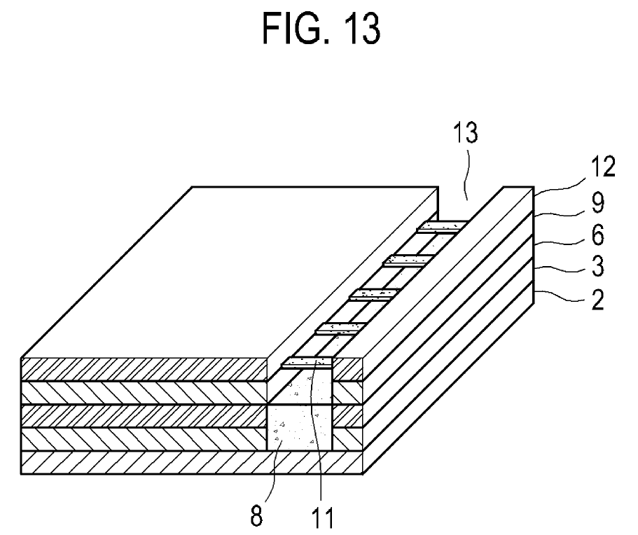

Referring to FIG. 13, the third and fourth photoresist layers 9, 12 are then patterned by photolithography or other equivalent process to define a recess 13 passing through the third and fourth photoresist layers 9, 12 just above the conductor block 8. Photolithography or other equivalent processes are performed to remove a desired portion of the third photoresist layer 9 disposed under the fourth photoresist layer 12 to a desired depth. It should be noted that the third and fourth photoresist layers 9, 12 are patterned away to expose the top surface of the conductor block 8 through the recess 7. As shown in FIG. 13, the third and fourth photoresist layers 9, 12 are removed away to expose end portions of the nano material strands 11 through the recess 13. It should be noted that all the nano material strands 11 extending in the grooves 10 of the third photoresist layer 9 are exposed in part through the recess 13.

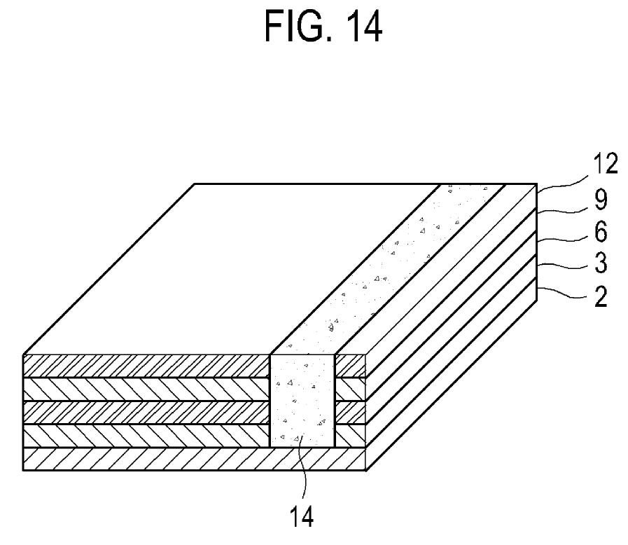

As shown in FIG. 14, a conductive material is filled in the recess 13 to physically and electrically contact and enclose the exposed portions of the nano material strands 11 so as to provide a conductor block 14. As a result, the nano material strands 11 are guaranteed to make electrical contact with the conductor block 14. In one embodiment, the conductive material may include, for example, but is not limited to, Ag, Cu, Al, etc. Further, the conductor block 14 may be attached to the conductor block 8.

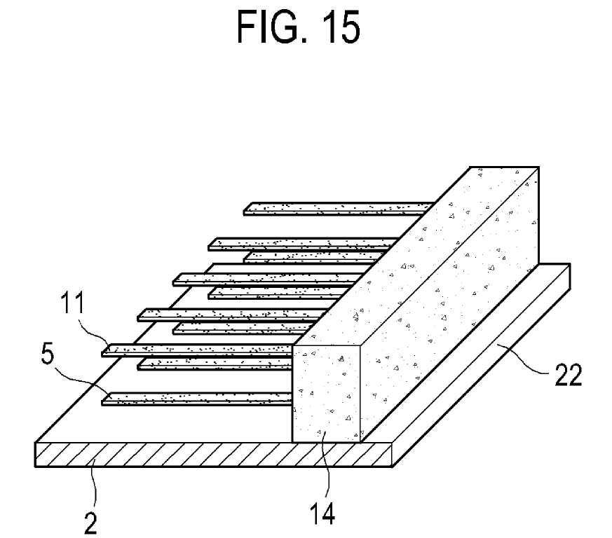

Thereafter, the remaining photoresist layers 3, 6, 9, 12 are completely removed by an appropriate lithography or etching process or equivalents thereof as shown in FIG. 15. As a result, there remains a nano material cluster structure on the substrate 2, including the nano material strands 5 and the nano material strands 11 respectively extended from a conductor block 14 comprised of the conductor blocks 8, 14 directly contacting each other.

In one embodiment, the first and second nano material strands 5, 11 may be trimmed so as to form an almost identical length.

For the trimming process, for example, a conventional ion beam milling process, which burns the end portions of the nano material strands 5, 11 exceeding a preset length, may be selected. However, it should be noted herein that other processes may be used in lieu thereof

Further, in one embodiment, the substrate 2 may be detached from the structure by an appropriate process such as photolithography, chemical lithography, etc. If the first and second photoresist layers 3, 5 are patterned away to leave a part of the first photoresist layer within the recess 7, then the substrate 2 is naturally detached at the removal of the remaining photoresist layers 3, 6, 9, 12. If the substrate 2 is detached from the structure, then the remaining nano material cluster structure is provided as a separate article, which may be used as a stand alone device or may be incorporated into other devices as a component.

In this embodiment explained above with reference to FIGS. 1 to 15, the nano material cluster structure includes two layers including the nano material strands, each of which has an end portion stuck to the conductor block. However, in another embodiment, the nano material cluster structure may include three or more layers of the nano material strands. According to the number of repeating the above series of steps, i.e., depositing and patterning a photoresist layer to make grooves, filling the grooves with nano materials, depositing and patterning another photoresist layer to make a recess, and filling the recess with conductive material, the number of nano strand layers included in the nano material cluster structure is determined. Further, in this embodiment, the recesses 7, 13 are made at different stages and the conductor blocks 8, 14 are made separately. However, in another embodiment, the recesses 7, 13 are made at one stage and the conductor blocks 8, 14 are made together after pattering the recesses 7, 13.

### Embodiment 2

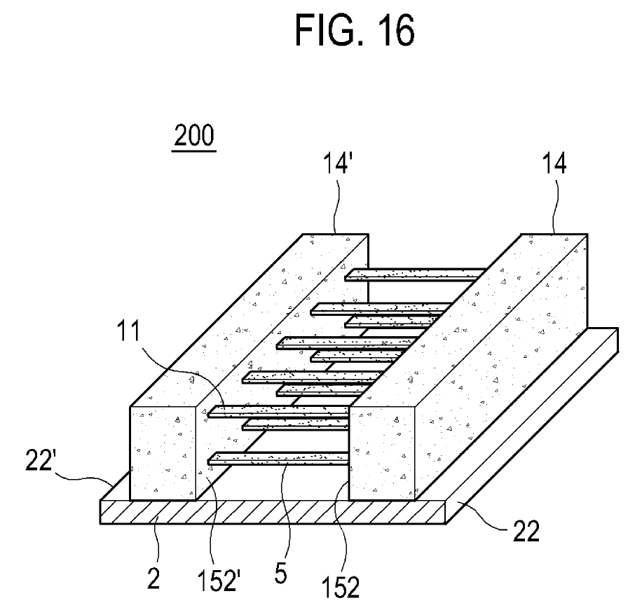

FIG. 16 shows a schematic diagram of a nano material cluster structure 200 in accordance with yet another embodiment. It should be noted that in FIG. 16, similar or corresponding elements of the nano material cluster structure 200 to those of the nano material cluster structure 100 shown in FIG. 1 are indicated by the same or similar reference numerals.

As shown in FIG. 16, the nano material cluster structure 200 is different from the nano material cluster structure 100 shown in FIG. 1 only in that the nano material structure 200 may further include a conductor block 14′ arranged in parallel to the conductor block 14 and the nano material strands 5, 11 may be extended from the conductor block 14 to the conductor block 14′ such that two end portions of the nano material strands 5, 11 are inserted into the respective conductor blocks 14, 14′. Thus, except for such difference from the nano material cluster structure 100 shown in FIG. 1, detailed explanations regarding each element of the structure 200 are omitted herein.

As shown in FIG. 16, the conductor block 14 may be formed on the substrate 2 to longitudinally extend in line with one edge 22 of the substrate 2, while the conductor block 14′ may be formed on the substrate 2 to longitudinally extend in line with another edge 22′ of the substrate 2 opposite to the edge 22. The conductor block 14′ may also have the shape of a rectangular hexahedron including longitudinally extending top and bottom surfaces. The conductor block 14′ may also have longitudinally extending lateral surfaces and two end surfaces arranged between and in perpendicular to the top and bottom surfaces. The bottom surface of the conductor block 14′ may be attached to the top surface of the substrate 2. The conductor block 14′ may be formed of one or more electrically conductive materials, including, for example, but not limited to, Ag, Cu, Al, etc.

As described above, the nano material cluster structure 200 may also include the first and second sets of nano material strands 5, 11. The first set of nano material strands 5 may be arranged to extend from the conductor block 14 to the conductor block 14′ such that the two end portions of each of the first nano material strands 5 are inserted into the respective conductor blocks 14, 14′. The second set of nano material strands 11 may also be arranged to extend from the conductor block 14 to the conductor block 14′ such that the two end portions of each of the second nano material strands 11 are inserted into the respective conductor blocks 14, 14′.

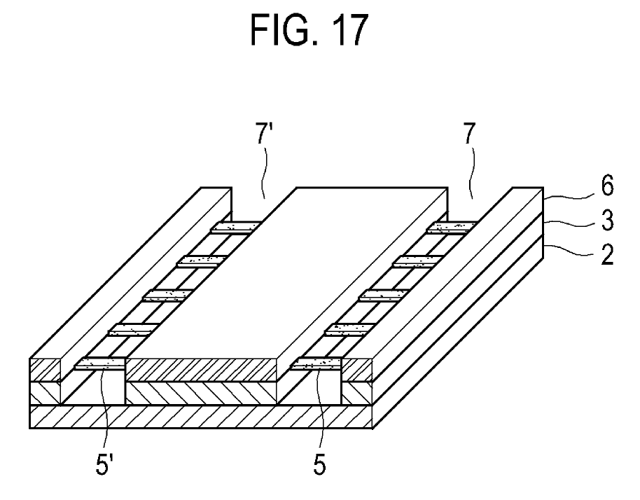

FIGS. 17 to 20 show a series of steps for preparing a nano material cluster structure in accordance with yet another embodiment. In this embodiment, the processing method explained above with reference to FIGS. 2 to 15 is in part modified as described below.

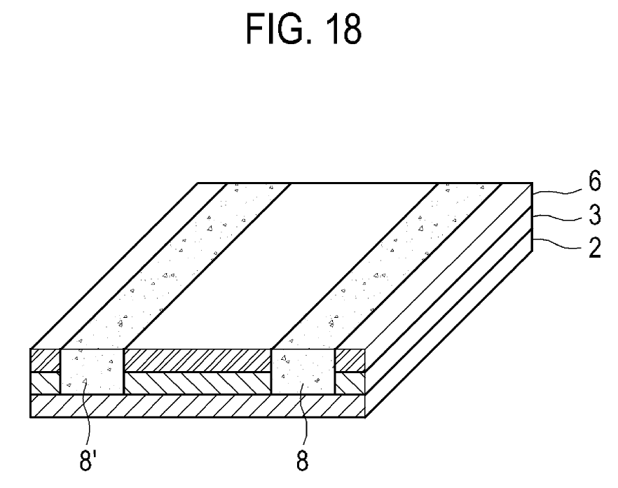

First, a series of steps for depositing and patterning a first photoresist layer to make grooves, filling the grooves with nano material, and depositing a second photoresist layer are performed as shown in FIGS. 2 to 6. Thereafter, as shown in FIG. 17, the first and second photoresist layers 3, 6 on the substrate 2 are patterned by photolithography or other equivalent processes to define two recesses 7, 7′ respectively passing through the first and second photoresist layers 3, 6. The recess 7 is formed proximate to one edge 22 of the substrate 2 to have a width corresponding to a resultant conductor block 14. Further, the recess 7′ is formed proximate to another edge 22′ of the substrate 2 to have a width corresponding to a resultant conductor block 14′. The first and second photoresist layers 3, 5 are patterned away to expose the substrate 2 through the recesses 7, 7′. Alternatively, in yet another embodiment, the first and second photoresist layers 3, 5 may be patterned away to leave a part of the first photoresist layer within the recesses 7, 7′. Contrary to only one recess 7 shown in FIG. 7 through which each of the nano material strands 5 extending in the grooves 4 is exposed in part, the first and second layers 3, 6 are patterned away to define the two recesses 7, 7′. This is so that both end portions of the nano material strands 5, 5′ are respectively exposed through each recess 7, 7′. Thereafter, the two recesses 7, 7′ are filled with conductive materials to form two conductor blocks 8, 8′, as shown in FIG. 18.

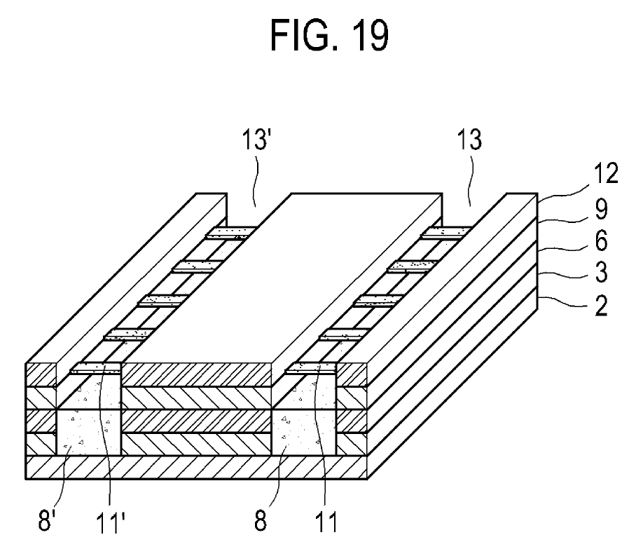

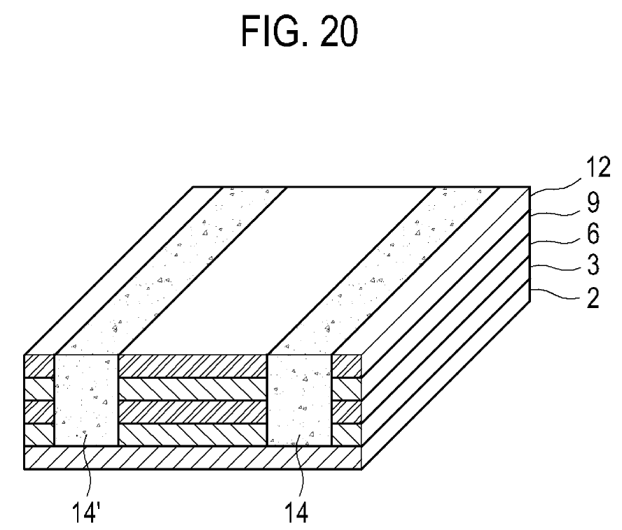

A series of steps for depositing and patterning a third photoresist layer to make grooves, filling the grooves with nano materials, and depositing a fourth photoresist layer are then performed, as shown in FIGS. 9 to 12. Thereafter, as shown in FIG. 19, the third and fourth photoresist layers 9, 12 are patterned by photolithography or other equivalent processes to define two recesses 13, 13′ respectively passing through the third and fourth photoresist layers 9, 12 just above the conductor blocks 8, 8′. It should be noted that the third and fourth photoresist layers 9, 12 should be patterned away to expose the top surfaces of the conductor blocks 8, 8′ through the recesses 13, 13′. Contrary to only one recess 13 shown in FIG. 13 through which each of the nano material strands 11 extending in the grooves 4 is exposed in part, the third and fourth layers 9, 12 are patterned away to define the two recesses 13, 13′. This is so that both end portions of the nano material strands 11, 11′ are respectively exposed through each recess 13, 13′. Thereafter, the two recesses 13, 13′ are filled with conductive materials to form two conductor blocks 14, 14′, as shown in FIG. 20.

As shown in FIG. 16, the remaining photoresist layers 3, 6, 9, 12 are then completely removed to obtain the nano material cluster structure. It should be noted that except for the above difference explained above, the nano material cluster structure 200 and the preparation method thereof are identical to those depicted in FIGS. 1 to 15.

### Embodiment 3

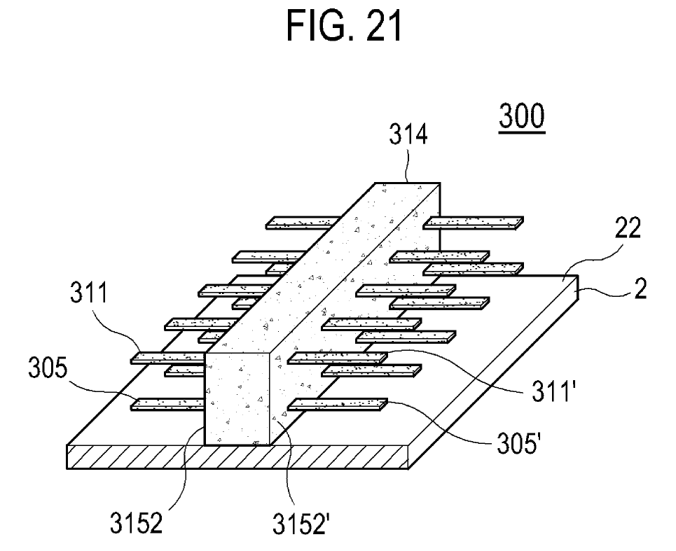

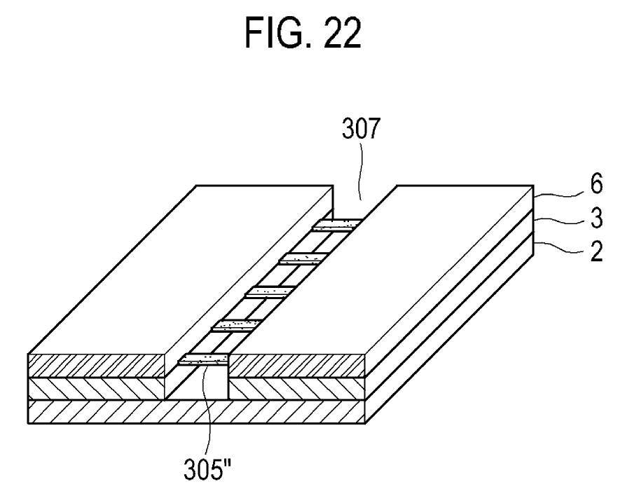

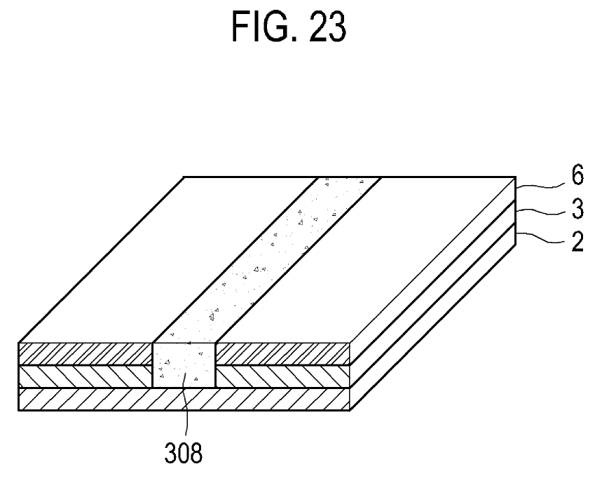

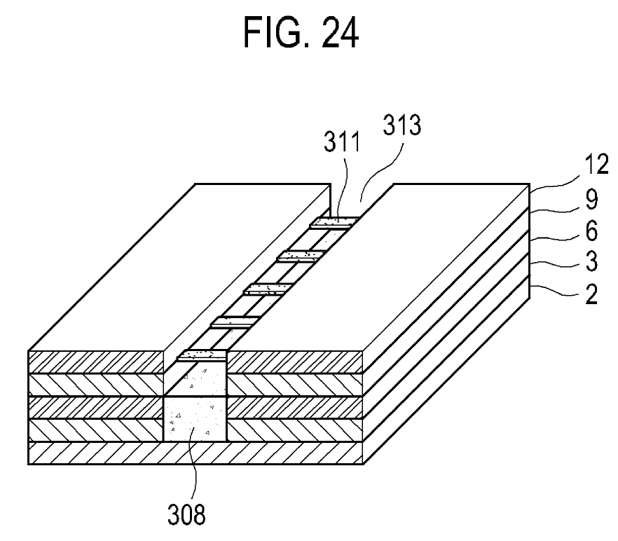

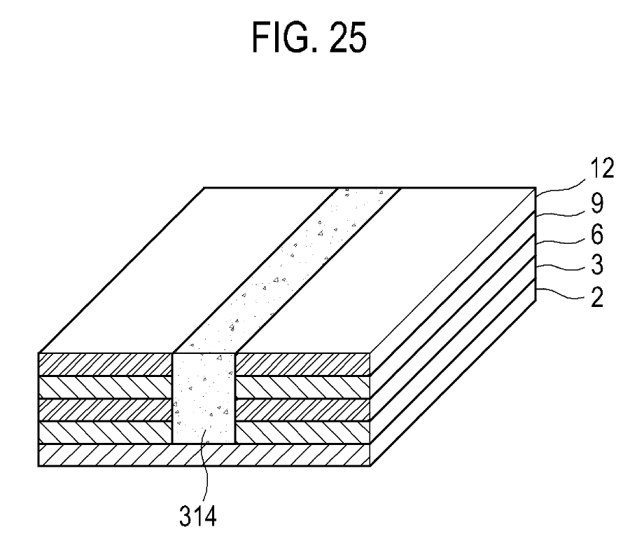

FIG. 21 shows a nano material cluster structure 300 in accordance with still yet another embodiment. It should be noted that in FIG. 21, similar or corresponding elements of the nano material cluster structure to those of the nano material cluster structure 100 in FIG. 1 are indicated by the same or similar reference numerals.

As shown in FIG. 21, the nano material cluster structure 300 is different from the nano material cluster structure 100 shown in FIG. 1 only in that a conductor block 314 may be formed in the middle of the substrate 2 and the nano material strands 305, 311 and nano material strands 305′, 311′ respectively protrude from respective opposite lateral surfaces 3142, 3142′ of the conductor block 314. Thus, except for such difference from the nano material cluster structure 100 shown in FIG. 1, detailed explanations regarding each element of the structure 300 are omitted herein.

As described above, the conductor block 314 may be formed in the middle of the substrate rather than proximate to the edge 22 of the substrate 2. The shape, direction of arrangement and materials for the conductor block 314 are identical to those of the conductor block 14 shown in FIG. 1. As shown in FIG. 21, the nano material strands 305, 311 protrude from one lateral surface 3142 of the conductor block 14. Further, the nano material strands 305′, 311′ protrude symmetrically from the other lateral surface 3142′ of the conductor block 314.

As shown in FIG. 21, the nano material strands 311, 311′ may be arranged in a coplanar relationship with each other and further in parallel with the substrate 2. Also, the nano material strands 305, 305′ may be arranged in a coplanar relationship with each other and further in parallel with the substrate 2 below the nano material strands 311, 311′. In the nano material cluster structure 300, the nano material strands 305, 305′, 311, 311′ are provided with the end portions left open, i.e., not bounded. It should be noted that the nano material strands 305, 305′, 311, 311′ may be used to transmit not only electricity but also lights across the structure 300.

FIGS. 22 to 25 show a series of steps for preparing a nano material cluster structure in accordance with yet another embodiment. In this embodiment, the processing method explained above with reference to FIGS. 2 to 15 is in part modified as described below.

First, a series of processes for depositing and patterning a first photoresist layer to make grooves, filling the grooves with nano material, and depositing a second photoresist layer are performed as shown in FIGS. 2 to 6. Thereafter, as shown in FIG. 22, the first and second photoresist layers 3, 6 on the substrate 2 are patterned by photolithography or other equivalent processes to define a recess 307 passing through the first and second photoresist layers 3, 6. The recess 307 is formed so as to cover the middle of the grooves 4 (not the end portions) and to have a width corresponding to a resultant conductor block 314. The first and second photoresist layers 3, 5 are patterned away to expose the substrate 2 through the recess 307. Alternatively, in another embodiment, the first and second photoresist layers 3, 5 may be patterned away to leave a part of the first photoresist layer within the recess 307. Contrary to the recess 7 shown in FIG. 7 through which end portions of the nano material strands 305 (or 305′) extending in the grooves 4 are exposed, the first and second layers 3, 6 are patterned away to define the recess 307 so that the continuous portions of the nano material strands 305 (or 305′) are exposed in part through the recess 307. Thereafter, the recess 307 is filled with conductive materials to form a conductor block 308, as shown in FIG. 23.

A series of steps for depositing and patterning a third photoresist layer to make grooves, filling the grooves with nano materials, and depositing a fourth photoresist layer are then performed as shown in FIGS. 9 to 12. Thereafter, as shown in FIG. 24, the third and fourth photoresist layers 9, 12 are patterned by photolithography or other equivalent processes to define a recess 313 passing through the third and fourth photoresist layers 9, 12 just above the conductor block 308. It should be noted that the third and fourth photoresist layers 9, 12 should be patterned away to expose the top surfaces of the conductor block 308 through the recess 313. Contrary to the recess 13 shown in FIG. 13 through which end portions of the nano material strands 11 extending in the grooves 104 are exposed, the third and fourth layers 9, 12 are patterned away to define the recesses 313 so that the continuous portions of the nano material strands 311 (or 311′) are exposed through the recess 313. Thereafter, the recess 313 is filled with conductive materials to form a conductor block 314, as shown in FIG. 25.

The remaining photoresist layers 3, 6, 9, 12 are then completely removed to obtain the nano material cluster structure as shown in FIG. 21. It should be noted that except for the above difference, the nano material cluster structure 300 and the preparation method thereof are the same as those depicted in FIGS. 1 to 15.

It should be noted that, if not deviating from the idea of the present disclosure, any processing method, which may be well known to or may be newly developed by those skilled in the art, may be selected for the above deposition, patterning, lithography processes, etc. It should be also noted that, if not deviating from the idea of the present disclosure, any materials that may be well known to or may be newly discovered by those skilled in the art may be selected for the nano materials or the conductive materials. Aspect ratios of the nano materials discussed in this disclosure, for example, not as a limitation, may fall in the range of, e.g., greater than 20, 50, 100, 1000, 10000, etc.

The above nano material cluster structures may be used as electronic, magnetic or optical components by themselves or as parts of more complicated electronic, magnetic or optical devices. Especially, the above nano material cluster structures may be highly useful in the field of biotechnology including various sensors, detectors and the like. According to the present disclosure, other nano material cluster structures may be provided and used for various universal electronic, magnetic or optical devices.

In light of the present disclosure, those skilled in the art will appreciate that the methods described herein may be implemented in hardware, software, firmware, middleware or combinations thereof and utilized in systems, subsystems, components or sub-components thereof For example, a method implemented in software may include computer code to perform the operations of the method. This computer code may be stored in a machine-readable medium, such as a processor-readable medium or a computer program product, or transmitted as a computer data signal embodied in a carrier wave, or a signal modulated by a carrier, over a transmission medium or communication link. The machine-readable medium or processor-readable medium may include any medium capable of storing or transferring information in a form readable and executable by a machine (e.g., by a processor, computer, etc.).

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A nano material cluster structure, comprising:
a conductor block having a surface; and
a plurality of first nano material strands protruding from the surface of the conductor block, wherein the plurality of first nano material strands extend from the conductor block in a coplanar relationship.

2. The nano material cluster structure of claim 1, further comprising a plurality of second nano material strands protruding from the surface of the conductor block, wherein the plurality of second nano material strands extend from the conductor block in a coplanar relationship.

3. The nano material cluster of claim 2, wherein the second nano material strands are parallel with the first nano material strands.

4. The nano material cluster structure of claim 1, wherein the conductor block generally has a shape of a rectangular hexahedron.

5. The nano material cluster structure of claim 1, wherein the conductor block includes at least any one of Ag, Cu and Al.

6. The nano material cluster structure of claim 1, wherein the first nano material strands are arranged in parallel with each other.

7. The nano material cluster structure of claim 2, wherein the second nano material strands are arranged in parallel with each other.

8. The nano material cluster structure of claim 1, wherein the first nano material strands are equally spaced apart from each other.

9. The nano material cluster structure of claim 2, wherein the second nano material strands are equally spaced apart from each other.

10. The nano material cluster structure of claim 2, wherein the first and second nano material strands include at least any one of carbon nanotubes or carbon nanowires.

11. The nano material cluster structure of claim 2, wherein the first and second nano material strands all have a same length.

12. A nano material cluster structure, comprising:
two conductor blocks; and
a plurality of first nano material strands each having two end portions, wherein the plurality of first nano material strands extend from one of the two conductor blocks to the other conductor block such that the two end portions of each of the first nano material strands are inserted into the respective conductor blocks.

13. The nano material cluster structure of claim 12, wherein the two conductor blocks are arranged in parallel with each other.

14. A nano material cluster structure, comprising:
a conductor block having two opposing surfaces;
a first set of nano material strands protruding from one of the two opposing surfaces of the conductor block; and
a second set of nano material strands protruding from the other of the two opposing surfaces,
wherein the first set of nano material strands are coplanar with the second set of nano material strands.

15. A nano material cluster structure, comprising:
a conductor block having a surface and including electrically conductive substances therein; and
a plurality of first nano material strands protruding from the surface of the conductor block while forming an electrical contact therewith, wherein the plurality of first nano material strands extend from the conductor block in a first coplanar relationship, and wherein the relationship includes at least one of a direction of at least one of the first strands, a length of at least one of the first strands protruding from the block, and an arrangement between at least two of the first strands.

16. The nano material cluster structure of claim 15, further comprising a plurality of second nano material strands protruding from the surface of the conductor block, wherein the plurality of second nano material strands extend from the conductor block in a second coplanar relationship which includes at least one of a direction of at least one of the second strands, a length of at least one of the second strands protruding from the block, and an arrangement between at least two of the second strands.

17. A nano material cluster structure, comprising:
a plurality of nano material strands each defining a proximal end and a distal end, the nano material strands being arranged such that each of the strands is at least partially parallel to at least one of other strands; and
at least one electrically-conductive block for enclosing the proximal ends of the strands, the block forming an electrical contact with the strands while maintaining a desired arrangement, wherein the structure is capable of forming an open electric circuit from the block to the distal ends of the strands.

18. A nano material cluster structure, comprising:
a plurality of nano material strands each defining a proximal end and a distal end, the nano material strands being arranged such that each of the strands is at least partially parallel to at least one of other strands; and
at least one partially transparent block for enclosing the proximal ends of the strands while maintaining a desired arrangement, wherein the structure is capable of providing an optical path from the proximal ends of the strands to the block.

19. A nano material cluster structure, comprising:
a plurality of nano material strands each defining a hollow interior and proximal and distal ends, the nano material strands being arranged such that each of the strands is at least partially parallel to at least one of other strands; and
at least one partially transparent block for enclosing the proximal ends of the strands while maintaining a desired arrangement, wherein the structure is capable of providing an optical path from the distal ends of the strands to the block through the hollow interiors of the strands.

20. A nano material cluster structure, comprising:
two conductor blocks spaced apart from each other by a preset distance and each including electrically conductive substances therein; and
a plurality of first nano material strands each interposed between the blocks while forming an electrical contact with each of the blocks, wherein the plurality of first nano material strands extend between the conductor blocks in a first coplanar relationship, and wherein the first coplanar relationship includes at least one of a direction of at least one of the strands, a length of at least one of the strands extending between the blocks, and an arrangement between at least two of the strands.

21. A method of preparing a nano material cluster structure, comprising:
providing a layered structure having multiple layers on a substrate, the multiple layers including a layer having nano material strands therein;
patterning the layered structure to define one or more recesses, wherein the nano material strands are partially exposed through the one or more recesses; and
filling the one or more recesses with a conductive material to enclose the partially exposed nano material strands.

22. The method according to claim 21, further comprising detaching the substrate.

23. The method according to claim 21, wherein the nano material strands are arranged in parallel to each other.

24. The method according to claim 21, wherein the one or more recesses are respectively arranged in perpendicular to an extending direction of the nano material strands.

25. The method according to claim 21, wherein the nano material strands include at least any one of carbon nanotubes and carbon nanowires.

26. The method according to claim 21, wherein at least one of the recesses is defined so that end portions of the nano material strands are exposed through the recess.

27. The method according to claim 21, wherein providing the layered structure comprises:
depositing a first photoresist layer on the substrate;
patterning the first photoresist layer to define multiple grooves;
filling the grooves with nano materials to make the nano material strands match the grooves respectively; and
depositing a second photoresist layer to cover the first photoresist layer having the nano material strands therein.

28. The method according to claim 27, further comprising removing the first and second photoresist layers after filling the conductive material.

29. The method according to claim 27, wherein a thickness of the nano material strands is smaller than a depth of the multiple grooves.

30. The method according to claim 28, further comprising trimming ends of the nano material strands so as to be left open rather than enclosed by the conductive material such that the nano material strands have a substantially equal length.

31. A method of preparing a nano material cluster structure, comprising:
providing a formable layer on a substrate;
forming a plurality of grooves in the layer in a presser pattern;
positioning nano material strands in the grooves in the pattern; and
enclosing one ends of the strands with an electrically conductive block while maintaining the pattern, wherein the structure defines an electric circuit which in turn defines a pattern identical to that of the grooves and which extends from the block to opposite ends of the strands.

32. The method according to claim 31, further comprising detaching the substrate after the step of enclosing the one ends of the strands.

33. The method according to claim 31, wherein the step of positioning comprises arranging at least a substantial number of the nano material strands in parallel to each other.

34. The method according to claim 31, further comprising repeating the steps of providing, forming and positioning to thereby stack a plurality of the electric circuits upon one another.

35. The method according to claim 31, wherein the step of positioning comprises depositing at least any one of carbon nanotubes and carbon nano wires in the grooves.

36. The method according to claim 31, further comprising enclosing opposite ends of the strands with another electrically conductive block while maintaining the pattern, wherein the structure defines an electric circuit which in turn defines a pattern identical to that of the grooves and which extends from the block to the another block.

37. The method according to claim 31, wherein the steps of providing and forming comprise:
depositing a first photoresist layer on the substrate;
patterning the first photoresist layer to define the grooves;
filling the grooves with the nano materials to thereby align the nano material strands with the grooves; and
depositing a second photoresist layer to cover the first photoresist layer having the nano material strands therein.

38. A method of preparing a nano material cluster structure, comprising:
providing a formable layer on a substrate;
forming a plurality of grooves in the layer in a presser pattern;
positioning nano material strands in the grooves in the pattern; and
enclosing one ends of the strands with at least partially transparent block while maintaining the pattern, wherein the structure defines an optical path which in turn defines a pattern identical to that of the grooves and which extends from the block to the strands.
